(19) United States
(12) Patent Application Publication
(10) Pub. No.: US 2015/0118391 A1
(43) Pub. Date: Apr. 30, 2015

(54) THERMAL MANAGEMENT CIRCUIT MATERIALS, METHOD OF MANUFACTURE THEREOF, AND ARTICLES FORMED THEREFROM

(71) Applicant: Rogers Corporation, Rogers, CT (US)

(72) Inventor: Brett W. Kilhenny, Mystic, CT (US)

(21) Appl. No.: 14/522,758

(22) Filed: Oct. 24, 2014

Related U.S. Application Data
(60) Provisional application No. 61/895,126, filed on Oct. 24, 2013.

(51) Int. Cl. H05K 1/02; F21V 29/00; H05K 3/30; H05K 3/06; H05K 3/38; H05K 3/44; H05K 1/18; H05K 3/46

(52) U.S. Cl. CPC H05K 1/0206; H05K 1/18; F21V 29/004; H05K 3/4661; H05K 3/064; H05K 3/382; H05K 3/445; H05K 3/30; H05K 2201/068; H05K 2203/0723; H05K 2203/0502
USPC 427/97.2; 174/252; 361/712; 362/373; 205/95; 205/125; 205/109; 29/854

(57) ABSTRACT

A thermal management circuit material comprises a thermally conductive metallic core substrate, metal oxide dielectric layers on both sides of the metallic core substrate, electrically conductive metal layers on the metal oxide metal oxide dielectric layers, and at least one through-hole via filled with an electrically conductive metal-containing core element connecting at least a portion of each of the electrically conductive metal layers, wherein the containing walls of the through-hole via are covered by a metal oxide dielectric layer connecting at least a portion of the metal oxide dielectric layers on opposite sides of the metallic core substrate. Also disclosed are methods of making such circuit materials, comprising forming metal oxide dielectric layers by oxidative conversion of a surface portion of the metallic core substrate. Articles having a heat-generating electronic device such as an HBLED mounted in the circuit material are also disclosed.

### BACKGROUND

This invention relates to thermal management circuit materials comprising one or more electrically conductive vias. Such circuit materials can be used to support optoelectronic, microwave, RF, power semiconductor, or other electronic devices.

While there are a variety of circuit materials available today, there is especially a demand for circuit materials for high power applications, that is, applications generating high specific energy or involving high operating temperature. In particular, semiconductors that are designed to carry relatively high current loads can have an upper limit for operating temperatures, above which the semiconductor can fail, jeopardizing the operational reliability of the entire circuit. Circuit materials designed for thermal management have been used where there is a need to dissipate heat, in order to maintain the operating temperature in a desired range. Such heat-dissipating thermal management circuit materials can be useful with high power diodes, transistors, or the like. For example, an optoelectronic, microwave, RF, switching, amplifying, or other electronic device can be mounted on a substrate that provides support and acts to remove heat from the device. Such a substrate requires sufficient dielectric strength and a good thermal conductivity.

A thermal management circuit material typically has a thermally conductive base, or core substrate (typically a thermally conductive metal such as aluminum) for conducting heat away from a high power component. A dielectric layer insulates the core substrate from a patternable or patterned electrically conductive metal layer (typically a metal such as copper) disposed on the dielectric layer. Such a circuit material is sometimes referred to as an insulated metal substrate or IMS. It is known to insulate a thermally conductive base on one or both sides using a dielectric material. Such insulated metal substrates can also be referred to as Metal Core Printed Circuit Boards (MCPCB). Thermal management circuit materials can also comprise a substrate layer attached to a heat sink, optionally through a layer of thermal interface material. However, a thermal management circuit material can comprise a metal board or supporting frame, as a core substrate, with or without a separately configured heat sink.

The dielectric material on the thermal management circuit material should have a high dielectric strength to secure electric insulation from circuitry associated with the electronic device, thereby avoiding or preventing short-circuiting. The dielectric layer or layers disposed on a thermally conductive core substrate, however, can limit the desired thermal conductivity of the circuit material. Thus, the dielectric material should have sufficient thermal conductivity to dissipate heat generated by the device, which otherwise can negatively affect performance, reliability and lifetime of a device mounted on the circuit material. In general, a dielectric material having increased dielectric strength enables a circuit material to have a thinner insulating layer, which can reduce thermal resistance (with the same insulating material). Other electronic properties of a dielectric material can be relevant also. For instance, for RF and microwave applications it can also be beneficial that the thermal management circuit material comprises a dielectric material that has a high dielectric constant.

Variously many organic and inorganic dielectric materials are known in the prior art. In particular, it is known to insulate a thermally conductive base using a dielectric material that is polymeric, for example epoxy, fluoropolymer, polyimide or their composites charged with thermally conductive ceramic powders. Such polymeric dielectric materials, however, can have low thermal conductivities and, moreover, can exhibit insufficient thermal stability necessary for high operating temperatures, e.g., greater than 150° C. On the other hand, inorganic dielectric materials can have higher thermal conductivity (typically greater than or equal to about 20 Watts per meter-degree Kelvin or W/m-K), low coefficients of thermal expansion (typically less than or equal to 10 parts per million per degree centigrade, ppm/° C.), and high thermal stability (e.g., up to about 900° C.). Inorganic dielectric materials, however, can require an adhesive in order for an electrically conductive metal layer to adhere. Inorganic dielectric materials can have lower dielectric strengths, typically less than or equal to about 20 kiloVolts per mm of dielectric thickness (V/mil) and, therefore, can require a relatively thick layer (greater than or equal to 10 mils/250 micrometers), which in turn can detract from thermal conductivity. This can be disadvantageous for applications that increasingly require smaller components and higher thermal conductivity.

An inorganic dielectric layer for an insulated metal substrate can be obtained by various techniques. A dielectric layer can be formed directly on a heat sink by an anodizing process as described in GB 2162694 or by Plasma Electrolytic Oxidation (PEO) as described in US Pat. 2008257585A1. Alternatively, Shashkov et al., in WO 2012/107754, have disclosed a method of forming a non-metallic coating or layer on a metallic substrate in an electrolysis chamber by applying a sequence of voltage pulses of alternating polarity to electrically bias the metallic substrate with respect to an electrode. According to this technique, pulses of higher voltage can be applied to a metallic substrate, while significantly reducing or eliminating undesirable levels of micro-discharge, which can have a deleterious effect on desired coating properties. The process of WO 2012/107754 can advantageously employ an electrolyte that is colloidal, comprising solid particles dispersed in an aqueous phase. The solid particles can be transferred to and incorporated within the growing non-metallic coating, wherein they can favorably modify the characteristic pore dimensions and crystal structure of the growing coating, which in turn can provide improved hardness, thermal conductivity, and electrical breakdown.

WO 2012/1077555, also to Shashkov et al., discloses that an insulated metal substrate, as made by the process of WO 2012/107754, can be used for supporting a device and can be affixed to a heat sink on one side. The ceramic dielectric coating on the insulated metal substrate can have a dielectric strength greater than 50 KV mm⁻¹ and a thermal conductivity of greater than 5 Wm-¹K⁻¹. Shashkov et al. show an insulated metal substrate (IMS), insulated on one side and having a heat sink on the other side, for use with a packaged device or chip such as an LED. Thermal vias through the ceramic coating can connect to the metal heat sink to provide further heat transfer. WO 2012/107754 generally discloses that such thermal vias can be formed by a masking process prior to the formation of the dielectric coating, by an etching process after the coating has been formed, or by laser ablation of the ceramic dielectric coating.

What is needed is a thermal management circuit material for high power applications that have the desired thermal and electrical properties for use with high power devices such as an HB LED (high-brightness light-emitting diode). It is desirable for the circuit material to be relatively thin. Such circuit materials have dielectric insulation on both sides of a core metal substrate for electrically conductive metal layers on opposite sides of the core metal substrate, wherein electrically conductive vias connect the electrically conductive metal layers. Such a thermal management circuit material is desired in which the dielectric insulation provides a good balance of high thermal conductivity and low electrical conductivity, which circuit material can be used in mounting one or more electronic devices for high power applications such as a high-brightness light-emitting diode (HBLED) package. In addition, it is desirable that such a thermal management circuit material be capable of being efficiently and economically made.

### SUMMARY

The above-discussed and other drawbacks and deficiencies of prior art thermal management circuit materials can be overcome or alleviated by a circuit material comprising a thermally conductive metallic core substrate; a first metal oxide dielectric layer on a first side of the metallic core substrate; a second metal oxide dielectric substrate layer on a second side of the thermally conductive metallic core substrate, which second side is opposite from the first side of the metallic core substrate; a first electrically conductive metal layer on the first metal oxide dielectric layer; a second electrically conductive metal layer on the second metal oxide dielectric layer; at least one though-hole via, in the metallic core substrate, filled with an electrically conductive metal-containing core element electrically connecting at least a portion of each of the first and second electrically conductive metal layers, wherein walls defining the through-hole via are covered with an intermediate metal oxide dielectric layer transversely joining the first metal oxide dielectric layer and the second metal oxide dielectric layer, which metal oxide dielectric layers insulate the electrically conductive metal. Thus, the first, second, and intermediate dielectric layers (collectively “dielectric layers”) can form a continuous dielectric layer (forming no holes in the dielectric layers that can cause a short circuit) insulating the thermally conductive metallic core substrate from the electrically conductive metal layers and the metal-containing core element in the through-hole via, wherein the dielectric layers are made by a process comprising oxidation of a surface portion of the metallic core substrate. In one embodiment, the metal oxide dielectric layer can have a thermal conductivity of greater than or equal to about 5 Watt per meter-degree Kelvin and/or a dielectric strength of greater or equal to 50 KV mm⁻¹.

Optionally an adhesion-improving layer can be present between the dielectric layers and the electrically conductive metal layers or metal-containing core element in the through-hole via. In one embodiment, a metallic adhesion-improving layer is present between the first electrically conductive metal layer and the first metal oxide dielectric layer, between the second electrically conductive metal layer and the second metal oxide dielectric layer, and between the metal-containing core element in the through-hole via and the intermediate metal oxide layer, but removed from other areas of the metal oxide dielectric layers not in contact with the electrically conductive metal layers.

Another aspect of the invention is directed to an article comprising an electronic device selected from the group consisting of an optoelectronic device such as an LED (light emitting diode), especially including HB LEDs (high-brightness LEDs), an RF device, a microwave device, a switching, amplifying or other electronic device supported on the above-described circuit material having a patterned electrically conductive layer, i.e. in which the circuit material is used for mounting an electronic device, for example, to obtain a packaged LED comprising an insulated substrate. The electronic device can be a heat-generating semiconductor, diode, or transistor.

Yet another aspect of the invention is directed to a method of making a circuit material comprising providing a thermally conductive metallic core substrate; forming (for example, drilling) at least one through-hole via in the metallic core substrate; forming metal oxide dielectric layers on opposite sides and in the through-hole vias of the metallic core substrate by a process comprising oxidatively converting, in a surface layer of the metal of the metallic core substrate, metal to metal oxide; applying an electrically conductive metal such as copper at least on opposite sides of the metallic core substrate. The resulting circuit material thus made can have a thermal conductivity of greater than or equal to about 50 Watt per meter-degree Kelvin.

One embodiment of the invention is directed to a method of making a circuit material comprising providing an aluminum core substrate; drilling a pattern of conductive through-hole vias in the aluminum core substrate; forming alumina (aluminum oxide or Al₂O₃) dielectric layers on opposite sides and in the vias of the aluminum core substrate by a process comprising oxidatively converting aluminum of the core substrate to alumina, wherein the method comprises positioning the aluminum core substrate in an electrolysis chamber containing an aqueous electrolyte and an electrode, wherein at least the surface of the aluminum core substrate and a portion of the electrode is in contact with the aqueous electrolyte, and electrically biasing the aluminum core substrate with respect to the electrode by applying voltage, specifically a sequence of voltage pulses of alternating polarity, for a predetermined period of time, wherein positive voltage pulses anodically bias the aluminum core substrate with respect to the electrode and negative voltage pulses cathodically bias the aluminum core substrate with respect to the electrode, wherein the amplitude of the positive and negative voltage pulses can be controlled, such that the surfaces of the alumina dielectric layers, including the containing walls of the through-hole vias, can then be selectively plated with copper.

The thermal management circuit material can have a desirable combination of properties including metal oxide dielectric layers that provide relatively high thermal conductivity, low electrical conductivity, and high thermal and dimensional stability, wherein the combination of properties is superior to that found in comparable circuit materials. Advantageously, the circuit materials can also be provided in thin cross-section. Furthermore, the circuit materials can be made into larger panels, which can be later subdivided, resulting in a more economic process for making a superior product.

The features and advantages of the present invention will be appreciated and understood by those skilled in the art from the following detailed description and drawings.

### BRIEF DESCRIPTION OF THE DRAWINGS

Referring now to the exemplary drawings wherein like elements are numbered alike in the several FIGURES:

FIG. 1 is a perspective view of a thermal management circuit material according to one embodiment of the present invention;

FIG. 2 is a micrographic image of a cross-section of a thermal management circuit material such as shown in FIG. 2.

FIGS. 3A, 3B, and 3C show a heat management circuit material that can be used for mounting an LED package according to one embodiment of the invention, wherein FIG. 3A to 3C are a top plan, bottom and sectional view, in which circuit material tge core substrate has been drilled with a plurality of through-hole vias; and

FIGS. 4A and 4B are cross-sectional views of two alternative embodiments of a heat thermal management circuit material in which an LED device has been mounted.

### DETAILED DESCRIPTION

It has been found by the inventors hereof that a thermal management circuit material can be advantageously produced that comprises a thermally conductive metallic core substrate, metal oxide dielectric layers on opposite substantially flat sides of the metallic core substrate, electrically conductive metal layers on each of the metal oxide metal oxide dielectric layers, and at least one through-hole via filled with an electrically conductive metal-containing core element, connecting at least a portion of each of the electrically conductive metal layers. In an embodiment, the containing walls of the through-hole via are covered by a layer of metal oxide dielectric material that continuously connects to metal oxide dielectric layers on the opposite sides of the metallic core substrate, collectively forming “metal oxide dielectric insulation” for the metallic core substrate from the electrically conductive metal layers and the electrically conductive metal-containing core element in the through-hole via.

The metal oxide dielectric insulation can be formed by a process comprising oxidation of metal in a surface portion of the metallic core substrate. Also disclosed are articles having an electronic device such as an HBLED mounted on the circuit material.

The metal oxide dielectric layers can be designed to both provide excellent thermal conductivity and dielectric strength, as well as other desirable electrical properties. The circuit material can have a thermal conductivity of greater than or equal to about 50 Watt per meter-degree Kelvin. Advantageous physical properties can also be obtained, including a z-axis coefficient of thermal expansion of less than or equal to 25 ppm/° C. Furthermore, the metal oxide dielectric layers can provides excellent thermal stability, for example, at operating temperatures of 500° C. or greater. Finally, the metal oxide dielectric layers can provide desirable chemical stability to subsequent processing of the circuit material. Such a balance of properties compares favorably to that found in comparable circuit materials, whether using organic, inorganic, or organic/filler-based dielectric materials. In one embodiment, the metal oxide dielectric layers comprise alumina, although other metal oxides and combinations thereof can be present, as discussed below.

Compared to organic dielectric materials, the metal oxide dielectric layers do not present adhesion problems to the thermally conductive core metal substrate. Thus, the circuit material can be efficiently prepared by eliminating the need for intervening adhesive (i.e., adhesive-improving) layers between the dielectric layer and the metal core substrate, which adhesive layers can be detrimental because they can increase the thermal resistance of the circuit material.

Compared to the use of other inorganic materials, such as aluminum nitride (AlN), the metal oxide dielectric layers of the present invention can be made using relatively inexpensive materials and manufacture. Furthermore, the thermal resistance Rₜₕ (the reciprocal of thermal conductivity) can be significantly less than that of an AlN dielectric layer. In one embodiment, the metal oxide dielectric layers are made by a process that provides superior balance of thermal conductivity or dielectric strength, even compared to alternative processes of making similar metal-oxide containing compositions from metal in the metallic core substrate, based on superior physical properties so the metal oxide material.

In particular, the circuit materials can be made by a process that surprisingly allows opposite sides of the metallic core substrate and the containing walls of the through-hole via to be simultaneously and effectively covered with the same metal oxide material during the same oxidation process. This is surprising, particularly given the configuration of the through-hole vias and the risk of short-circuiting if inadequately insulated. Furthermore, such a process can eliminate the need for the more difficult production of a through-hole via by drilling through both a metal oxide dielectric layer and the metallic core substrate, which can require laser drilling. Thus, the present circuit materials can be made by a process comprising drilling the metallic core substrate, without a ceramic or other inorganic dielectric layer. Thus, mechanical drilling can be used to save the expense of laser drilling, while also limiting the scrap impact of the drilling process to low cost aluminum (and not more expensive AlN or other ceramic material).

A further advantage is that a circuit material can be manufactured in the form of a panel that has a substantially larger dimension that a current industry of 4.5-inches by 4.5-inches (4.5×4.5 inch) for an LED. In the method of the present invention, it is practical to manufacture a panel that can then be subdivided into multiple panels of such standard size each for use in an HBLED or other LED. Alternatively, larger formats for mounted LEDs can be considered, for example, 8-inch wafers. In contrast, ceramic blanks in the prior art are difficult to manufacture in sizes substantially larger than a 4.5×4.5 format.

The metallic core substrate on which the dielectric layers are to be formed can be masked such that the metal oxide coating is only applied to a predetermined region where dielectric functionality is desired. Alternatively, the metallic core substrate can be completely coated with the metal oxide layers. The metallic core substrate can be of any desired shape. Specifically, the metallic core substrate can be a substantially flat thin board such as used in HBLEDs.

The terms metallic or metal, as used herein, are intended to describe broad classes of such material, including semi-metallic compositions. Thus, these terms describe elemental metals such as pure aluminum or magnesium, as well as alloys of one or more elements, and intermetallic compounds. Practically, the metallic core substrates can be commercially available metallic or semi-metallic compositions that can function in the present context. Specifically the metal for the core metal substrate can be aluminum, magnesium, titanium, zirconium, tantalum, beryllium, and an alloys or intermetallic thereof. More specifically, the metal is substantially aluminum or an alloy thereof, specifically predominantly or essentially aluminum.

The terms “metal oxide” or “metal-oxide-containing,” in reference to a dielectric layer or insulation, refers to materials based on one or more metal oxides, although other compounds, for example, metal hydroxides can be present in lesser amounts. For example, dielectric layers based on the oxidation of aluminum metal to aluminum oxide (Al₂O₃ or alumina) can comprise other compounds such as aluminum hydroxide or Al(OH)₃, as can be produced during. Also, as discussed below solid particles such as glass or other non-metallic materials can be incorporated into a dielectric layer during its growth by electrolysis. A metal oxide dielectric layer can comprise at least 60 wt. % of one or more metal oxides, specifically at least 80 or 90 wt. % of one or more metal oxides, for example, aluminum oxide.

The one or more through-hole vias in the metallic core substrate can be formed by selectively removing metal from the thermally conductive metallic core substrate to create a hole extending from one side to the other side of the metallic core substrate. This can be accomplished prior to formation of the metal oxide dielectric layers. Specifically, the through-hole via can been formed by mechanically drilling through the metallic core substrate. Alternatively, the through-hole via can be formed by etching or laser drilling. Advantageously, therefore, the through-hole via need not be formed by drilling or etching through a metal oxide dielectric layer, which adds expense and difficulty.

The cross-section of a through-hole via can have various cross-sectional shapes, including circular or non-circular shapes. The through-hole via can have various diameters or equivalent diameters, for example, in the range of 10 to 1000 micrometers, specifically 50 to 500 micrometers, more specifically 100 to 300 micrometers, most specifically 150 to 250 micrometers. The cross-sectional shape and/or dimensions of each of a plurality, or pattern of, through-hole vias can be independently predetermined. In one embodiment, through-hole vias in the circuit material have a circular shape of substantially uniform diameter.

A plurality of vias can be present in the circuit material, for example 1 to 40, specifically 2 to 16, per individual circuit, with 50 to 35,000 circuits per panel, for example, a 4.5 inch by 4.5 inch panel, in order to allow for connections between first and second electrically conductive metal layers. Thus, for example, a circuit material can be made in the form of panel having 1,000 individual circuits, each containing 4 vias resulting in 4,000 vias per 4.5×4.5 panel. In the manufacture of packaged LED's, each panels can be subsequently divided, for example with a diamond blade, into numerous units each having, for example 30 light-emitting diodes for a 60 Watt bulb.

Since the through-hole vias can be formed before the formation of the insulating dielectric layers, so that a dielectric layer can also be formed in the vias, it follows that a later application of an adhesion-improving layer (for example, a metallic seed layer) on the dielectric layers can also result in the adhesion-improving layer also being present on the dielectric layer on the walls of the through-hole via, as well as under electrically conductive metal applied to the insulated core metallic substrate. Thus, in one embodiment, there is an adhesive-promoting layer, for example, a sputtered metallic seed layer, in the through-hole via between the electrically conductive metal-containing core element in the via and the metal oxide layer on the containing walls of the through-hole via, which adhesive-promoting layer can be uniformly and simultaneously applied to the entire surface of the dielectric layers on the thermally conductive core substrate and then removed where copper or other metal plating is not desired.

The metal oxide dielectric layers can have a thickness of about 1 to 50 micrometers (about 0.04 mils to about 2 mils), specifically about 0.13 to about 1.2 mils (about 5 to about 30 micrometers), and more specifically about 10 to about 30 micrometers, most specifically 12 to 20 micrometers. In an embodiment, the thicknesses, on average, of the first and second dielectric layers on the opposite sides of the metallic core substrate and in the through-hole vias can be substantially uniform, for example, within 50 percent, more specifically within 25 percent, most specifically within 10 percent of each other.

In one embodiment, the thickness of the metal-oxide dielectric layers is specifically less than 40 micrometers, and specifically less than 20 micrometers, more specifically less than 15 micrometers. The thinner the metal oxide dielectric layer, the more effective the thermal transfer across the layer. Thus, it can be advantageous to provide a metal oxide dielectric layer having thicknesses even lower, for example, 5 micrometers to 15 micrometers.

The metal oxide dielectric layers that insulate the thermally conductive core substrate can be formed at least in part by oxidation of a portion of the surface of a metallic core substrate. A circuit material according to an aspect of the invention can comprise metal oxide dielectric layers that have been applied selectively to a portion of a metallic core substrate or to the entire metallic core substrate. Accordingly, in one embodiment, the metal oxide dielectric insulation on the metallic core substrate is formed by a method comprising positioning a metallic core substrate, having one or more through-hole vias formed therein, in an electrolysis chamber containing an aqueous electrolyte and an electrode. The metallic core substrate can be, for example, in the form of a circuit board, specifically a thin panel having at two substantially flat sides in which one or more through-hole vias have been drilled or otherwise made. In order to convert and grow a metal oxide layer in a top surface portion of the metallic core substrate, a voltage can be applied to the metallic core substrate to electrically bias the metallic core substrate with respect to the electrode. At least the surface of the metallic core substrate on which it is desired to form a metal oxide dielectric layer, specifically both sides of the metallic core substrate and the containing walls of the through-hole via, and a portion of the electrode are in contact with the aqueous electrolyte.

In one embodiment, a sequence of voltage pulses of alternating polarity is applied for a predetermined period. Positive voltage pulses anodically bias the substrate with respect to the electrode, and negative voltage pulses cathodically bias the substrate with respect to the electrode. The amplitude of the positive voltage pulses can be potentiostatically controlled, that is controlled with respect to voltage, and the amplitude of the negative voltage pulses can be galvanostatically controlled, that is controlled by reference to current. Such a method of forming a metal oxide dielectric layer in the present circuit materials is, for example, disclosed in detail in WO 2012/1077555 and WO 2012/107754, which publications are hereby incorporated by reference in their entirety. By applying a sequence of voltage pulses of alternating polarity in which positive pulses are potentiostatically controlled and negative pulses are galvanostatically controlled, pulses of high voltage can be applied to the core metal substrate without inducing substantial levels of micro-discharge. By minimizing or avoiding micro-discharge events during the formation of metal oxide dielectric layers, surface roughness and the magnitude of the coating porosity can be controlled. This has been found to effectively and continuously coat the hole-through vias, despite their finely shaped nature, with an insulating layer of metal oxide, such that short circuits are avoided in the vias during operation of a mounted electronic device. Furthermore, single or continuous plating operation can, at the same time, “coat” the opposite sides of the metal substrate layer and through-hole vias, rather than necessitating separate or independently conducted unit operations, which makes for a very efficient manufacture. Furthermore, an excellent and advantageous balance of properties, especially in view of the advantageous manufacture and economical materials involved, can be obtained for the electrical properties of the dielectric layers, including the dielectric layer in finely featured through-hole.

In one embodiment of the process, in which a sequence of voltage pulses of alternating polarity is applied, current spikes during a voltage pulse can be avoided by shaping the positive and negative voltage pulses, for example, as described in disclosed in WO 2012/107754. In one embodiment, one or both of the positive and negative voltage pulses is substantially trapezoidal in shape. It is desirable to avoid, reduce or eliminate current spikes, because they are associated with the breakdown of the metal oxide dielectric layers and with micro-discharge. Micro-discharge can have deleterious effects on properties of the dielectric layer for insulation purposes. For example, micro-discharge can affect the structure or size of the pores in the metal oxide dielectric layer and, as a consequence, the dielectric strength of the dielectric layers.

In one embodiment, the conversion of material in the metallic core substrate to a surface layer of metal oxide insulation occurs during the positive voltage pulses in which the metallic core substrate is anodically biased with respect to the electrode, as follows. The metal oxide insulation is formed as oxygen-containing species in the aqueous electrolyte react with the metallic core substrate. Thus, successive positive voltage pulses can increase the metal oxide layer thickness. As the metal oxide layer increases in thickness, the electrical resistance of the insulation can increase and, according, less current may flow for the applied voltage. Thus, while it can be desirable that the peak voltage of each of the positive voltage pulses is constant over the predetermined period, the current flow with each successive voltage pulse may decrease over the predetermined period.

Furthermore, as the metal oxide insulation grows in thickness, the resistance of the metal oxide dielectric layer can increase and, therefore, the current passing through the metal oxide layers during each successive negative voltage pulse can cause resistive heating of the metal oxide layer. This resistive heating during negative voltage pulses can contribute to increased levels of diffusion in the metal oxide layers and, therefore, can assist the desired crystallization and grain formation within the developing dielectric layer. By controlling the formation of the metal oxide layers, wherein micro-discharge is avoided, a denser metal oxide layer for insulation can be formed, comprising crystallites or grain size of very fine scale in one preferred embodiment. The term grain size, as used herein, refers to the distance across the average dimension of a grain or crystal in a metal oxide dielectric layer.

In one embodiment, the pulse repetition frequency of the voltage pulses can be between 0.1 and 20 KHz, specifically between 1.5 and 15 KHz, or between 2 and 10 KHz. For example, advantageous pulse repetition frequencies can be 2.5 KHz or 3 KHz or 4 KHz. At low pulse repetition frequencies the metal oxide layers can undergo a period of growth followed by a period of ohmic heating. The resulting metal oxide layers can, therefore, obtain a coarser structure or surface profile than using a higher pulse repetition frequency, and a relatively higher pulse repetition frequencies can produce finer structures and smoother coating surfaces, although the growth rate and efficiency of the process may decrease to some extent.

The method of forming the metal oxide layer for insulation can be carried out in an electrolyte that is an alkaline aqueous solution, specifically an electrolyte having a pH of 9 or greater. Specifically, the electrolyte has an electrical conductivity of greater than 1 mS cm⁻¹. Electrolytes can include alkaline metal hydroxides, particularly those comprising potassium hydroxide or sodium hydroxide.

Advantageously, the electrolyte can be colloidal and comprise solid particles dispersed in an aqueous phase. Specifically, the electrolyte can comprise a proportion of solid particles having a particle size of less than 100 nanometers, wherein particle size refers to the length of the largest dimension of the particle.

Accordingly, in an embodiment, an electric field generated during the applied voltage pulses can cause electrostatically charged solid particles dispersed in the aqueous phase to be transported towards the surfaces of the metallic core substrate on which the metal oxide layers are growing. As the solid particles come into contact with the growing metal oxide layers, they can react with and/or physically intermix with, and become incorporated into, the layers. Thus, the metal oxide layers can optionally comprise both material formed by oxidation of a portion of the surface of the metallic substrate and colloidal particles derived from the electrolyte, when a colloidal electrolyte is used. Specifically, metal oxide solid particles dispersed in the aqueous phase can migrate, under the electric field of the electrolytic process, into pores of the growing metal oxide layers. Once within the pores, the solid particles can interact or react, for example by sintering processes, with both the metal oxide layer and with other solid particles that have migrated into the pores of the metal oxide layer. In this way, it is believed that the dimensions of the pores can be reduced and the metal oxide layers develop desirable nanoporosity. By reducing the porosity, the density of the metal oxide dielectric layer is increased. The reduction in the dimensions of the porosity through the metal oxide dielectric layers can substantially increase the dielectric strength and thermal conductivity of the layers, which has been found conducive to forming effective dielectric layers on the sides as well as in the through-hole vias of the metallic core substrate.

The electrolyte can comprise solid particles that are initially present in the electrolyte solution. Alternatively, solid particles can be added to the aqueous electrolyte during the electrolytic process. The solid particles can be ceramic particles, for example crystalline ceramic or glass particles, and a proportion of the particles can have maximum dimensions lower than 100 nanometers. In an embodiment, the solid particles can be one or more metallic oxides or hydroxides of an element selected from the group comprising silicon, aluminum, titanium, iron, magnesium, tantalum, the rare earth metals, and combinations thereof. In one embodiment, solid particles in a colloidal electrolyte can have a characteristic isoelectric point, and the pH corresponding to this isoelectric point can differ from the pH of the aqueous phase of the electrolyte by 1.5 or greater, so that, during the application of bipolar electric pulses, the solid particles can migrate towards the surface of the metallic core substrate under the influence of the applied electric field and become incorporated into the metal oxide insulation layers as it is being formed.

The method of forming the metal oxide layers, as described above, can be for a predetermined time. In particular, the process can be carried out for a time required to provide a desired or preselected thickness of the metal oxide dielectric layers, in order to provide the necessary insulation for an intended purpose or application. In one embodiment, the predetermined time can be between 1 minute and 2 hours, specifically 8 to 20 minutes. The rate of development of the layers of metal oxide material can depend on a number of factors including voltage, the waveform used to bias the substrate relative to the electrode, and/or the density and size of particles in the colloidal electrolyte when the method employs a colloidal electrolyte, as well as the time involved.

An apparatus suitable for forming metal oxide dielectric layers on the surface of a metallic core substrate can comprise, as would be appreciated by the skilled artisan, an electrolysis chamber for containing an aqueous electrolyte, an electrode locatable within the electrolysis chamber, and a power supply capable of applying a voltage, specifically a sequence of voltage pulses of alternative polarity between the metallic core substrate and the electrode. In an embodiment, the power supply comprises a first pulse generator for generating a potentiostatically controlled sequence positive voltage pulses for anodically biasing the metallic core substrate with respect to the electrode. The power supply can further comprise a second pulse generator for generating a galvanostatically controlled sequence of negative voltage pulses to cathodically bias the substrate with respect to the electrode.

Using such techniques, pores in the surface of the metal oxide dielectric layer of the circuit material can have an average diameter of less than 500 nanometers, specifically less than 400 nanometers, more specifically less than 300 nanometers, or less than 200 nanometers. The metal oxide dielectric layers can have a crystalline structure having an average grain size of less than 500 nanometers (0.5 microns).

Other methods of oxidizing the surface of the metallic core substrate can be used. For example, conventional anodizing, suitably optimized, can be used to form a metal oxide dielectric layer on the metallic core substrate, as well be appreciated by conventional anodizing. However, conventional anodizing tends to result in a dielectric layer that is more porous and usually has an amorphous structure (i.e., anodized coatings are rarely crystalline). A circuit material in which the dielectric layer has been formed by an anodic process can be limited to lower power applications in which the requirements are less rigorous. Still another method of oxidizing the surface of the metallic core substrate is by plasma electrolytic oxidation (PEO), which is a kind of anodizing as will be understood by the skilled artisan. The resulting dielectric layer can be crystalline, but tends to have a higher average porosity size, which can limit the dielectric properties and thermal conductivity.

Thus, it is desirable to obtain nanoscale porosity in the metal oxide insulation, which can contribute to desired and beneficial mechanical and electrical properties and allow for more effective insulation of through-hole vias. For example, a low average pore diameter can improve the dielectric strength of a layer. A high dielectric strength can mean that the metal oxide dielectric thickness required to achieve a predetermined minimum dielectric strength for a particular application can be lowered, which in turn can improve the thermal conductivity of the layer. Furthermore, a lower pore size can also improve the thermal conductivity of a metal oxide dielectric layer by improving the heat flow path through the layer. Specifically, in one embodiment, the pores of the metal oxide dielectric layers in the circuit materials has an average size of less than 400 nanometers, specifically less than 300 nanometers, to enhance the properties of the circuit material.

More specifically, the dielectric layers of the circuit material, according to one embodiment of the circuit material, is a crystalline alumina material that comprises grains having an average diameter of less than 200 nanometers, specifically less than 100 nanometers, for example about 50 nanometers or 40 nanometers. Such grains can be referred to as crystals or crystallites. Thus, a specific embodiment of a circuit material can comprise a aluminum oxide dielectric layer that is a nanostructured layer, wherein it has structural features having dimensions on a nanometer scale. Fine grain sizes can improve structural homogeneity and properties such as hardness, wear resistance and a smooth surface profile. Fine grain sizes can also increase thermal conductivity, dielectric strength, and dielectric constant of a dielectric material.

The electrically conductive metal layers that are disposed on the metal oxide dielectric layers are desirably both electrically conducting and thermally conducting. Useful electrically conductive metal layers for the formation of the circuit materials disclosed herein include stainless steel, copper, nickel plated copper, aluminum, copper-clad aluminum, zinc, zinc-clad copper, iron, transition metals, and alloys comprising at least one of the foregoing, with copper specifically useful and herein representative of an electrically conductive metal. There are no particular limitations regarding the thickness of the electrically conductive metal layers, nor are there any limitations as to the shape, size or texture of the surface of the conductive metal layer. In an exemplary embodiment, the conductive metal layer has a thickness of about 3 micrometers to about 200 micrometers, specifically about 5 micrometers to about 180 micrometers, and more specifically about 7 micrometers to about 75 micrometers. Where two or more conductive metal layers are present, the thickness of the two layers can be the same or different.

Electrically conductive metal layers comprising plated metals, specifically electroplated coppers, are particularly useful.

In one embodiment, the first and second electrically conductive metal layers, as well as the metal-containing core element in the through-hole via comprises copper. Copper plated electrically conductive metal layers can be further coated with silver or gold. The first and second conductive metal layers can have a total thickness of 1 to 250 micrometers, while the metallic core substrate can have a thickness of 0.5 to 1.5 mm, specifically 0.38 to 1.0 mm, corresponding to that of the through-hole vias present.

The first electrically conductive metal layer and the second electrically conductive metal layer, on opposite sides of the metallic core substrate, can be formed by a process selected from screen printing, metal ink printing, electroless metallization, galvanic metallization, chemical vapor deposition (CVD), and plasma vapor deposition (PVD) metallization. Thus, metallic foils or flex circuits can be eliminated. The electrically conductive metal layers can be patterned, as discussed further below, or un-patterned. The circuit material can advantageously be in the form of a panel having an area that is 15 to 20 times the area of a conventional panel that is 4.5 inches by 4.5 inches (ceramic blanks having an image area of 4 inches by 4 inches). Subsequently, such larger panel can be divided into individual units or used for making larger individual panels. For example, a circuit material that is 14 by 22 inches can be produced. A panel that has 14 inch by 22 inch dimensions, for example, can allow for an array of 3×5 panel images or the equivalent of 15 of the 4.5 inch×4.5 inch panels.

In general, the circuit material can be made by a method that overall comprises providing an metallic core substrate that is thermally conductive, forming at least one through-hole via in the metallic core substrate, forming metal oxide dielectric layers on opposite sides and in the through-hole via of the metallic core substrate by a process comprising oxidatively converting metal in an upper surface portion of the metallic core substrate to metal oxide, and then applying copper or other electrically conductive metal over the surface of at least thus formed metal oxide dielectric layers on the opposite sides of the metallic core substrate. (In the following discussion of the method, copper will be used to represent an electrically conductive metal, but it is to be understood not to limit the method to copper.)

In one embodiment, the through-hole via can be filled with a metal-containing core element electrically connecting the electrically conducive layers on opposite sides of the metallic core substrate during the plating of the electrically conductive metal layers, thereby forming a metal-containing core element that is bulk metal. Alternatively, the through-hole via can filled with a metal-containing core element electrically connecting the electrically conducive layers on opposite sides of the metallic core substrate following application of the electrically conductive metal layers, wherein the metal-containing core element is made by filling the through-hole via with metallic paste comprising metal particles and an organic resin, as will be appreciated by the skilled artisan. Thus, the through-hole vias can be filled after plating the electrically conductive metal layers, before, or at the same time. The first metal oxide dielectric layer, the second metal oxide dielectric layer, and/or the dielectric layer in the through-hole via can be coated with an adhesion-improving material, specifically after forming the metal oxide dielectric layers and before applying copper over the surface of the metal oxide dielectric layers. For example, a metallic seed layer can be coated onto the surface of the metal oxide layer in order to promote adhesion, or initiate plating, of the electrical conductive metal that is subsequently applied to form the electrically conductive metal layers. In one embodiment the metal seed layer is a sputtered layer comprising titanium (Ti) having a thickness of 100 to 150 nanometers, followed by 1-2 microns of copper (Cu).

In an embodiment, the method of making a circuit material can further comprise, after forming metal oxide dielectric layers and optionally coating with an adhesion-enhancing material, but before plating or otherwise applying copper, applying a resist coating to the coated or uncoated metal oxide dielectric layer, exposing the resist, and developing the resist. Accordingly, after plating copper onto the surface of the metal oxide dielectric layers, the resist can be stripped to produce a patterned electrically conductive metal layer. Alternatively, copper or other metal could be plate unpatterned and then selectively patterned by printing and etching the copper. Additive plating, however, can be more cost effective.

In the event that an optional metallic seed layer is sputtered onto the surface of the dielectric layers to improve the adhesion of the subsequent copper layer, the metallic seed layer can be removed (by etching, for example), after plating and patterning the copper onto the surface of the metal oxide dielectric layer.

In one embodiment, the method of making the circuit material comprises, after forming metal oxide dielectric layers, coating the layers with a metallic seed layer and, before applying the electrically conductive metal layers, applying a resist coating to the coated metal oxide dielectric layers, exposing the resist, developing the resist, plating electrically conductive metal layers over the metal oxide dielectric layers in areas where the resist has been developed, stripping the resist, and removing the metallic seed layers from areas that have not been plated with electrically conductive metal layers. In an alternative embodiment, the through-hole via can be filed with a metal paste, for example, a copper paste, and the electrically conductive metal layers on opposite sides of the metallic core substrate screen printed. The method can further comprise plating the surface of the copper layer with another metal, for example silver in order to protect the copper form oxidation and provides improved solderability. Subsequently, after plating one or more metals onto the surface of the metal oxide dielectric layers, a solder stop layer can be applied, as would be appreciated by the skilled artisan.

The method can further comprise, after plating copper onto the surface of the metal oxide dielectric layer, dividing the circuit material into a plurality of separate panels, each of which is about 4.5 inches by 4.5 inches (or within 50 percent, specifically within 30 percent, more percent within 10 percent of each dimension), as is a standard size for an individual LED unit or package.

The method can further comprise, after plating copper onto the surface of the insulated metallic core substrate, mounting an electronic device onto a surface of the circuit material to provide a product unit comprising the electronic device. In one embodiment, the electronic device can be an HBLED, as further discussed below.

In a more specific embodiment, the method of making a circuit material can comprise providing a metallic core substrate that is thermally conductive, drilling or otherwise forming at least one through-hole via in the metallic core substrate, forming metal oxide dielectric layers on opposite sides and in the via of the metallic core substrate by at least oxidatively converting metal of the metallic core substrate to metal oxide, optionally coating the metal oxide dielectric layers with an inorganic adhesion-improving material, wherein the method further comprises patterning electrically conductive metal layers. Specifically, the conductive metal layers can be patterned, in one embodiment, by applying a resist coating to the seed layer coated metal oxide dielectric layers and then, after exposing and developing the resist, plating copper over the surface of the metal oxide dielectric layers, stripping the resist, and then etching or otherwise removing the inorganic adhesion-improving material (for example, a sputter coated metal seed layer) from the non-plated areas of the metal oxide dielectric layers.

Thus, in the event of coating the metal oxide dielectric layers with an inorganic adhesion-improving layer that comprises a sputter coated metallic seed layer, for promoting adhesion of copper to a dielectric layer, the metallic seed layer can be subsequently removed from the non-plated areas of the metal oxide dielectric layers, in order to prevent a short circuit.

The dielectric strength of a metal oxide dielectric layer (and hence the circuit material) can be determined by measuring the dielectric breakdown voltage at multiple points on a sample, which is done by applying a voltage across two electrodes in intimate contact with either of the surfaces of the dielectric material and the inner core metal, such that the electrodes are separated by a distance equal to the thickness of the metal oxide dielectric layer at the point of measurement, wherein access for an electrode under the dielectric layer can be gained through the side or by removing a portion of the metal oxide layer. A direct current potential is placed across the electrodes, and the resistance to the voltage flow is measured as the voltage is increased. The voltage at which current begins to flow between the electrodes is noted as the dielectric breakdown voltage, and is measured in volts per mil of thickness (V/mil) or V/mm. Different dielectric breakdown voltages are associated with different materials of construction, and can vary depending on the composition of the dielectric layer, including the metal of the thermally conductive metal, the process of making converting a surface portion to a dielectric layer, and other compositional or processing factors. Thickness uniformity can also affect the dielectric breakdown voltage, with thinner regions showing lower dielectric breakdown voltages. In any case, however, continuous and effective coverage, as necessary, is important to prevent a short circuit.

In an embodiment, the circuit material can be supplied to a fabricator for attachment to a surface to provide a pathway for further heat dissipation away from the electronic device (e.g., a semiconductor device). Examples of such surfaces include surfaces of heat sinks and the like. Any suitable means can be used to attach the thermal management circuit material, or a circuit derived therefrom, to the surface. In an embodiment, the thermal management circuit material can be attached to a surface using a suitable thermally conducting layer or treatment, such as a thermally conducting adhesive. Such thermally conductive adhesives, where used, can be electrically conductive, semiconducting, or electrically non-conductive.

In an embodiment, the circuit material can be attached to a thermally conductive heat sink or the like that is substantially thicker than the metallic core substrate layer and that comprises a metal having a high thermal conductivity. Suitable metals having such characteristics include aluminum, copper, aluminum clad copper, and the like; or engineered thermal materials such as AlSiC, Cu/Mo alloys, and the like. Such thermally conductive heat sinks can comprise a single layer, multiple layers of a single material, or multiple layers comprising two or more different materials. The heat sink can be of a single uniform thickness, or can be of variable thickness. The thermally conductive base layer can include features such as cooling fins, tubes, or have tubes bored through the heat sink, through which a coolant can be passed to further increase the transfer of heat.

In a further embodiment, at least one additional layer including a dielectric layer, bond ply, conductive metal layer, a circuit layer, or a combination comprising at least one of the foregoing, can be disposed on the patterned electrically conducive layer, or circuit, in an appropriate manner to form a multilayer circuit.

The circuit materials described herein can have excellent properties, for example good dimensional stability and enhanced reliability, e.g., plated through-hole reliability, and excellent copper (metal) peel strength, particularly at high temperature.

In an embodiment, the circuit materials, specifically the metal oxide dielectric layers, are thermally stable at a temperature of greater than or equal to 150° C., specifically greater than or equal to 400° C., more specifically to 500° C. or more. Especially for use in combination with high power type solid-state devices, the circuit material can possess thermal properties that can tolerate exposure to temperatures encountered during processing operations such as soldering, brazing and welding. Temperatures of about 400° C., in either inert or hydrogen atmospheres, can be encountered. Typically, soldering operations are lower in temperature at about 200° C., while brazing operations can have higher temperatures in excess of about 425° C. Formation of copper oxide as a result of use with these high temperature processes can be mitigated by using a plating of a metal such as nickel, zinc, or other suitable metal that can mitigate the formation of oxides on the copper surface.

For some applications, the dielectric coating can have a high dielectric constant. For example, a high dielectric constant is desired when the circuit material is used in RF or microwave applications. Specifically, in an embodiment, the circuit material can comprise a dielectric coating with a dielectric constant greater than 7, specifically greater than 7.5, more specifically about 8 to 12, for example, 9 to 10.

In an embodiment, the dielectric material, or metal oxide layer, has a thermal conductivity of greater than or equal to 1 W/m-K, specifically greater than or equal to 5 W/m-K, more specifically greater than or equal to 10 W/m-K. Also, in an embodiment, the resulting circuit material, comprising the two metal oxide layers and the thermally conducting metal, has a thermal conductivity greater than or equal to 50 W/m-K, specifically greater than or equal to 120 W/m-K.

The metal oxide dielectric material can have a dielectric strength of greater than or equal to 800 volts per mil of thickness (or greater than 50 KV per mm (mm⁻¹), specifically 60 to 110 KV per mm.

The dissipation factor of the dielectric layer can be less than or equal to about 0.008 when measured at a frequency of 1 to 10 GHz.

The coefficient of thermal expansion CTE) of the dielectric material is desirably as low as possible. In addition to other benefits in thermal conductivity, low CTE places less strain on a circuit material prepared using the dielectric material during high temperature operation, where the CTE is more closely matched to that of the electrically conductive metal layer and the thermally conductive base layer. Matching of CTE's between layers is useful to prevent cracking, delamination, and failure of the circuit substrate during operation by adhesion failure.

In an embodiment, the dielectric material has a CTE of less than or equal to 50 ppm/° C., specifically less than or equal to 25 ppm/° C. Also, the metal oxide dielectric material can have a CTE of greater than 0 ppm/° C., specifically greater than or equal to 1 ppm/° C., more specifically greater than or equal to 2 ppm/° C. (In contrast, organic dielectric materials can have relatively high CTE's of about 25 to about 65 ppm/° C., which is significantly higher on average than that of adjacent metal layers.)

The circuit material having metal oxide dielectric layers can exhibit excellent resistance to chemicals encountered in printed circuit processes, as well as resistance to mechanical failures that can be caused by cutting, molding, broaching, coining or folding, which can result in damage such as cutting, ripping, cracking, or puncturing of one or more layers. The mechanical and electrical properties of the circuit material can provide an electrical mount that can withstand the processing conditions expected during subsequent assembly and during functional operation of the end product. For example, the circuit material can withstand exposure to chemicals encountered during printed circuit fabrication and the finished product can be mechanically durable enough to withstand mounting techniques and conditions, for example, in LED manufacture,

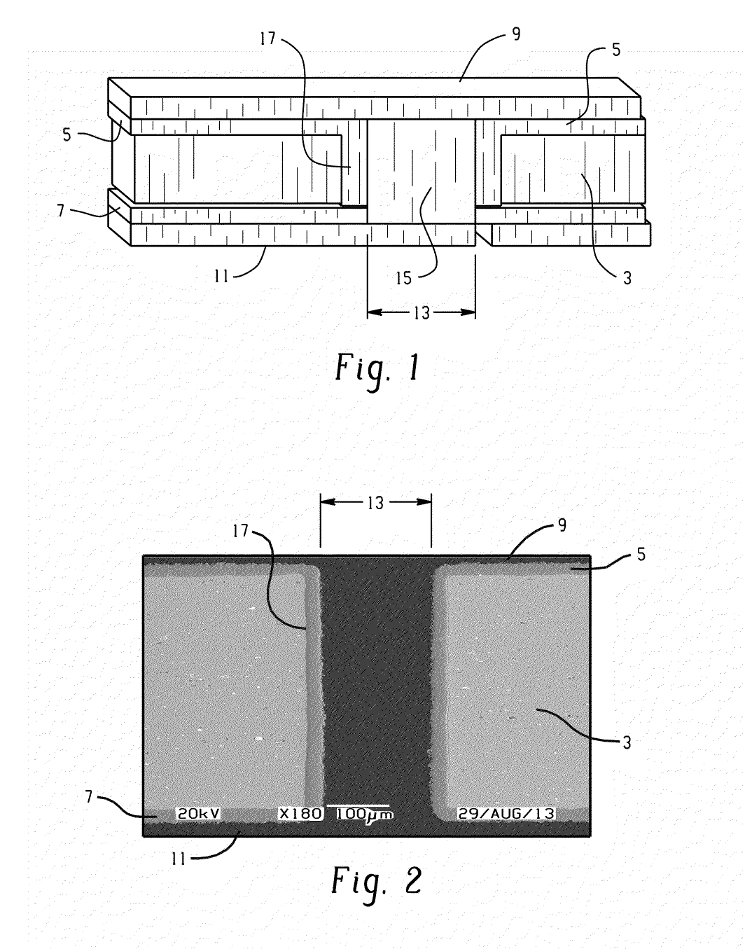

One embodiment of a thermal management circuit material is shown in FIG. 1. Referring to FIG. 1, the circuit material 1 comprises a thermally conductive metallic core substrate 3, a first metal oxide dielectric layer 5 on a first substantially flat side of the metallic core substrate 3; and a second metal oxide dielectric substrate layer 7 on a second side of the thermally conductive metallic core substrate, which second side is opposite from the first side of the metallic core substrate. A first electrically conductive metal layer 9 (unpatterned in this embodiment) comprises a conductive metal, for example copper, on the first oxide metal oxide dielectric layer 5. A second conductive metal layer 11 is disposed on the second metal oxide dielectric layer 7.

A through-hole via 13 is filled, for example plated, with an electrically conductive metal, which can also be copper, thereby at the same time forming, in the through-hole via, a metal-containing core element 15 that can electrically connect at least a portion of each of the first and second electrically conductive metal layers 9 and 11, wherein the through-hole via 13 is formed in (defined by) the thermally conductive metallic core substrate (and its metal oxide dielectric layer) and extending from one side to the other thereof.

Thus, the containing walls defining the through-hole via are covered with an intermediate or third metal oxide dielectric layer 17 that physically joins (continuously connects) the first metal oxide dielectric layer 9 to the second metal oxide dielectric layer 11, without containing gaps that could cause a short-circuit.

As mentioned above, an optional adhesion-improving layer, such as a metallic seed layer, of substantially lesser thickness than the metal oxide dielectric layers, specifically less than one-fourth the thickness of the dielectric layers, can be applied over the metal oxide dielectric layers prior to application of the electrically conductive metal layers. Hence, in the thermal management circuit material of FIG. 1, an adhesion-improving layer (not shown) can be present between the first electrically conductive metal layer 9 and the first metal oxide dielectric layer 5, between the second conductive metal layer 11 and the second metal oxide dielectric layer 7, and between the metal oxide layer 17 of the through-hole via 15 and the electrically conductive metal-containing core element 15 in the through-hole via 13. In one embodiment, the adhesion-improving layer is a metallic seed metal that comprises sputtered metal, for example copper and/or titanium.

FIG. 2 is a micrographic image of a magnified cross-section of a thermal management circuit material such as shown in FIG. 1 and made according to one embodiment of a process of making the circuit material. The corresponding features in FIGS. 1 and 2 are correspondingly numbered. The micrograph of FIG. 2 shows a surface portion of an aluminum core substrate 3 converted to alumina in the metal oxide dielectric layer 5, with a metallic core substrate 3 in the through-hole via in the aluminum core substrate 3.

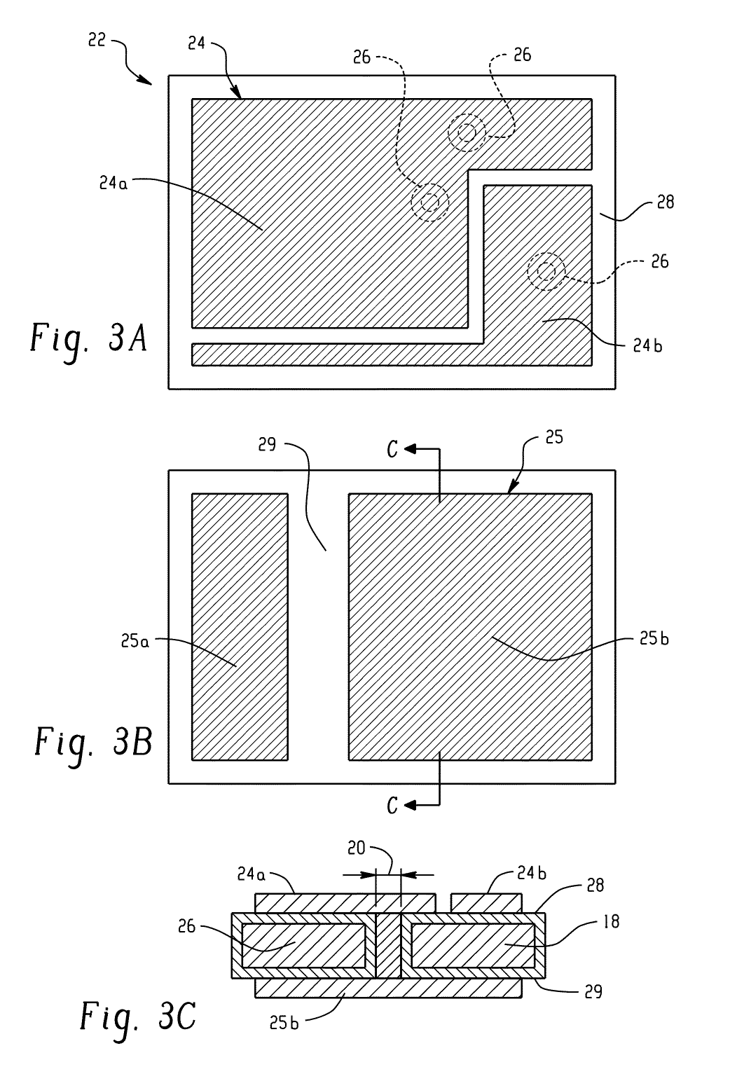

FIGS. 3A to 3C show a thermal management circuit material that can be used as a submount for an LED device package and which comprises a metallic core substrate 18 drilled with a plurality of through-hole vias 20 capable of being drilled prior to the formation of the metal oxide dielectric layer and copper plating. FIG. 3A shows a top plan view of the thermal management circuit material shown in bottom view in FIG. 3B and cross-sectional view (along line C-C of FIG. 3B) in FIG. 3C. In particular, FIG. 3A shows a top plan view of one embodiment of a thermal management circuit material 22 plated with a first electrically conductive metal layer 24, patterned into portions 24a and 24b, and second electrically conductive metal layer 25, patterned into portions 25a and 25b. In FIG. 3A, dotted lines indicate the location of a plurality of through-hole vias 26 under the first electrically conductive metal layer 24, portions of which are divided by areas of the first metal oxide dielectric layer 28. In FIG. 3B, the second metal oxide dielectric layer 29 can be seen in bottom view. In FIG. 3C, the through-hole via 20 filled with a metal-containing core element 26 is evident.

For certain applications, circuit materials can have a multilayered structure. For example, an additional layer or layers of dielectric material and associated metal conducting layers (not shown) can then be formed on the top of first and/or second electrically conductive metal layers 9 and 11 in the circuit material of FIG. 1. The additional dielectric layer or layers can comprise, for example, FR-4 fiberglass laminates or comprise an organic resin which, for example, can be selected from the group consisting of fluoropolymer, polyimide, polybutadiene, polyisoprene, poly(arylene ether) and combinations thereof. A multilayered structure formed on a base circuit material can enable a large number of external connections to be made.

As mentioned above, an electronic device can advantageously be attached to a thermal management circuit material such as shown in FIG. 3B, in order to provide high thermal conductivity. Thus, another aspect of the invention is directed to articles comprising an electronic device, for example, an optoelectronic device, an RF device, a microwave device, a power switch, a power amplifier, or other heat-generating component of a circuit, which electronic component or device can be supported on the first electrically conductive metal layer of the circuit material. Specifically, the electronic device can be type of semiconductor, for example, an LED, an HBLED, a MOSFET (metal-oxide-semiconductor field-effect transistor, an IGBT (insulated-gate bipolar transistor), or other heat-generating components for power applications, as would be appreciated by the skilled artisan. In certain applications, the article can comprises RF components, wherein circuits formed on the surface of the circuit material comprise high-Q input/output transmission lines, RF de-coupling and matching circuits.

In the case of an LED device (including specifically an HBLED), the LED device can be electrically connected to at least a portion of the first electrically conductive metal layer, for example, either by a metal wire or in a flip chip arrangement. Each of two ends of an LED can be sequentially connected to a voltage source to provide power to the LED. In one embodiment, a first electrically conductive metal layer and a second electrically conductive metal layer can be patterned and wires from the LED device can be connected to a first and second contact portion of the first electrically conductive metal layer. Furthermore, at least one conductive through-hole via can electrically connect each of the first and second contact portions to corresponding contact portions of the second electrically conductive metal layer on the circuit material.

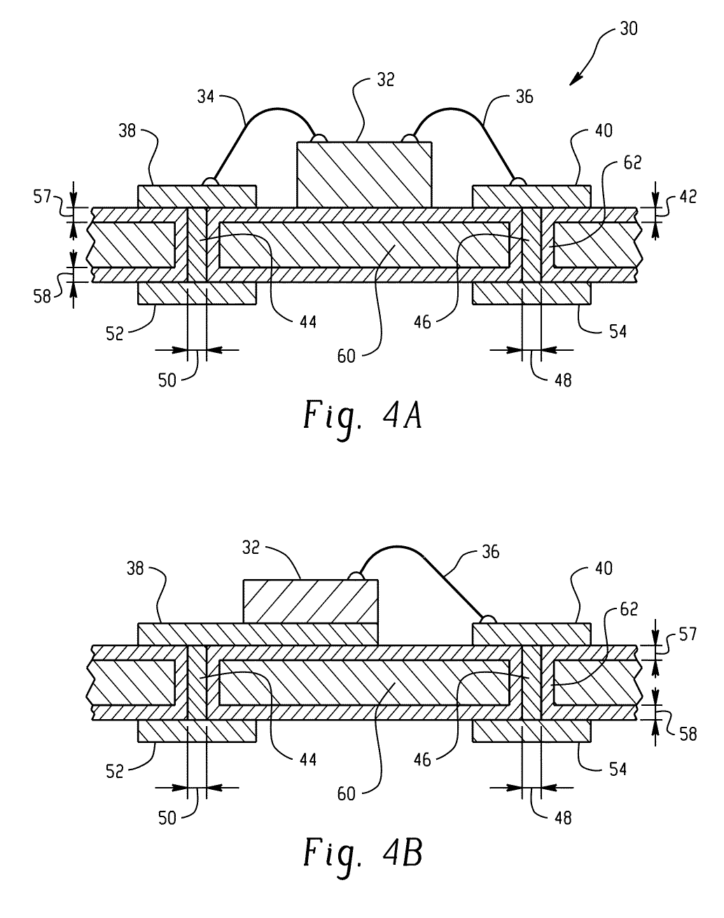

An LED device (“chip”) can be attached directly to the metal oxide dielectric layer on the thermally conductive metal core substrate, which metal oxide dielectric layer provides electrical insulation between the chip and the metallic core substrate or the LED device can be supported by an electrically isolated thermal or support pad on a metal oxide dielectric layer, which is isolated from the anode or cathode of the LED. The thickness of the metal oxide layer can be determined by the breakdown voltage requirement of the chip, and can be grown to the minimum thickness that meets the breakdown voltage requirement. This can provide the shortest thermal path between semiconductor components in the chip, which generates heat, and the metallic core substrate. FIGS. 4A and 4B show two different exemplary embodiments of an article 30 having an LED package or unit mounted on a base thermal management circuit material. The corresponding features in FIGS. 4A and 4B are correspondingly numbered. In the embodiment of FIG. 3A, an LED device 32 is disposed (mounted) on a circuit material that includes wire leads 34 and 36 electrically connected to contact pads 38 and 40, part of a first electrically conductive metal layer 42. Metal core elements 44 and 46 fill each of the through-hole vias 48 and 50 and electrically connect the electrical contact pads 38 and 40 in the first electrically conductive metal layer 42 to, respectively, electrical contact pads 52 and 54 in a second electrically conductive metal layer 56, which electrical contact pads can be part of a patterned circuit comprising plated copper. Integrally connected and substantially uniform metal oxide dielectric layers 57 and 58 on opposite sides of metallic core substrate 60, and cylindrically shaped intermediate metal oxide dielectric layer 62, insulate electrically conductive metal from the thermally conductive metallic core substrate 60. As discussed above, the dielectric layers comprise metal oxide that can be formed at least in part by oxidation of a surface portion of the metallic core substrate.

The embodiment of FIG. 4B show a flip chip arrangement in which an LED device 32 is supported on an electrical contact pad 38 of the first electrically conductive metal layer 42. One end of the LED has a wire 36 electrically connected to electrical contact pad 40 of the first electrically conductive metal layer 42. Metal core elements 44 and 46 fill each of the through-hole vias 48 and 50 and electrically connect the electrical contact pads 38 and 40 in the first electrically conductive metal layer to, respectively, electrical contact pads 52 and 54 in a second electrically conductive metal layer, which contact pads can be part of a patterned circuit comprising plated copper. Dielectric layers 56, 58, and 62 insulate the electrically conductive metal from the thermally conductive metallic core substrate 60, as discussed with respect to the embodiment of FIG. 4A.

The circuit materials disclosed herein are further illustrated by the following non-limiting examples.

### EXAMPLES

### Example 1

This example illustrates a method of forming aluminum oxide insulation on an aluminum core substrate. The aluminum core substrate is in the form of a plate of Al 6082 alloy having dimensions of 100 mm×100 mm×_{—}0.5 mm in which 1,092 through-hole vias are mechanically drilled, each through-hole via having a circular cross-section of 0.195 mm diameter.

The aluminum core substrate is placed in an electrolysis apparatus comprising a tank containing an electrolyte, and the aluminum core substrate and an electrode are coupled to a pulse power supply. A pulse generator is applied in a sequence of voltage pulses of alternating polarity between the substrate and the electrode. Positive voltage pulses are applied having a fixed positive voltage amplitude (Vₐ) in the range of 500 to 700 V, and negative voltage pulses had a negative voltage amplitude (V_{c}) continuously grown in a range from 0 to 500 V. The pulse repetition frequency is in the range of 1 to 3 KHz.

The pulses are applied for 12 minutes, whereby an aluminum oxide layer of the desired thickness is formed on the surfaces of the aluminum core substrate and in the through-hole vias.

FIG. 2 shows a micrographic image of a magnified cross-section of a thermal management circuit material made according to such process, in which a surface portion of an aluminum core substrate 3 has been converted to alumina in a metal oxide dielectric layer 5, with a metallic core substrate 3 in the through-hole via in the aluminum core substrate 3.

The singular forms “a,” “an,” and “the” include plural referents unless the context clearly dictates otherwise. The endpoints of all ranges directed to the same characteristic or component are independently combinable and inclusive of the recited endpoint. All references are incorporated herein by reference. As used herein and throughout, “disposed,” “contacted,” and variants thereof refers to the complete or partial physical contact between the respective materials, substrates, layers, films, and the like. Further, the terms “first,” “second,” and the like herein do not denote any order, quantity, or importance, but rather are used to distinguish one element from another.

While typical embodiments have been set forth for the purpose of illustration, the foregoing descriptions should not be deemed to be a limitation on the scope herein. Accordingly, various modifications, adaptations, and alternatives can occur to one skilled in the art without departing from the spirit and scope herein.

What is claimed is:

1. A thermal management circuit material, capable of use for mounting an electronic device, comprising:
a thermally conductive metallic core substrate;
a first metal oxide dielectric layer on a first side of the metallic core substrate;
a second metal oxide dielectric substrate layer on a second side of the thermally conductive metallic core substrate, which second side is opposite from the first side of the metallic core substrate;
a first electrically conductive metal layer on the first oxide metal oxide dielectric layer;
a second electrically conductive metal layer on the second metal oxide dielectric layer;
at least one through-hole via filled with an electrically conductive metal forming a metal-containing core element that electrically connects at least a portion of each of the first and second electrically conductive metal layers, wherein the walls defining the through-hole via have an intermediate metal oxide dielectric layer transversely joining the first metal oxide dielectric layer and the second metal oxide dielectric layer, which intermediate metal oxide dielectric layer insulates the metal-containing core element in the through-hole via from the thermally conductive metal core substrate;
wherein the first, second, and intermediate metal oxide dielectric layers are made by a process comprising oxidation of a surface portion of the metallic core substrate and wherein the first, second, and intermediate metal oxide dielectric layers collectively form metal oxide insulation for the thermally conductive metallic core substrate.

2. The circuit material of claim 1 wherein the first and second metal oxide dielectric layers have a thermal conductivity of greater than or equal to about 5 Watt per meter-degree Kelvin and a dielectric strength of greater than or equal to about 50 KV per mm.

3. The circuit material of claim 1 wherein the dielectric material is thermally stable at a temperature of greater than or equal to about 400° C. and wherein the dielectric layer has a coefficient of thermal expansion of 0 to about 25 parts per million per degree centigrade.

4. The circuit material of claim 1 wherein the circuit material, having patterned or unpatterned electrically conductive metal layers, forms a panel having an area that is 15 to 20 times the area of a conventional panel that is 4.5 inches by 4.5 inches.

5. The circuit material of claim 1, wherein the first, second electrically conductive metal layers and the metal-containing core element comprises copper, gold, silver, or a combination thereof and wherein the metallic core substrate comprises aluminum or an alloy of aluminum with one or more metals selected from the group consisting of magnesium, titanium, zirconium, tantalum, and beryllium.

6. The circuit material of claim 1 further comprises an adhesion-improving layer directly bonding the first electrically conductive metal layer to the first metal oxide dielectric layer, the second electrically conductive metal layer to the second metal oxide dielectric layer, and the electrically conductive metal-containing core element in the via to the intermediate metal oxide dielectric layer.

7. The circuit material of claim 6 wherein the adhesion-improving layer is a metallic seed layer for plating of the electrically conductive metal layers, which metallic seed layer of substantially lesser thickness than the metal oxide layer on which it is coated.

8. The circuit material of claim 1 wherein the through-hole via has been formed by selectively removing metal from the thermally conductive metallic core substrate to create a through-hole via extending from one side to the other side of the metallic core substrate, prior to formation of the metal oxide dielectric layers.

9. The circuit material of claim 8 wherein the through-hole via has been formed by drilling through the metallic core substrate.

10. The circuit material of claim 9 wherein the through-hole via has not been formed by drilling or etching through a metal oxide or ceramic dielectric layer.

11. The circuit material of claim 1 wherein there is a layer of sputtered metallic seed metal in the through-hole via between the electrically conductive metal forming the metal-containing core element in the via and the intermediate metal oxide layer forming the walls of the through-hole via.

12. The circuit material of claim 1 wherein the metal oxide dielectric layers are made by a process comprising electrolytic oxidation.

13. The circuit material of claim 12, wherein the metal oxide dielectric layers have a crystalline structure having an average grain size of less than 500 nanometers, wherein pores defined in a surface of the metal oxide insulation have an average diameter of less than 500 nanometers.

14. The circuit material of claim 1 wherein the electrically conductive metal layers are patterned.

15. An article comprising a heat-generating electronic device mounted on the circuit material of claim 1.

16. The article of claim 15 wherein the electronic device is selected from the group consisting of an optoelectronic device, an RF device, or a microwave device, a switching or amplifying semiconductor, or a power transistor, wherein the electronic device is supported on the first electrically conductive metal layer of the circuit material.

17. The article of claim 15 wherein the article comprises RF components and wherein circuits formed on the surface of the circuit material comprise high-Q input/output transmission lines, RF de-coupling and matching circuits, or power transistor.

18. The article of claim 15, wherein the first electrically conductive metal layer and the second electrically conductive metal layer are patterned and wherein an electrical connection is present between the electronic device and a first contact portion and between the electronic device and a second contact portion of the first electrically conductive metal layer and wherein at least one conductive via connects each of the first and second contact portions to corresponding contact portions of the second electrically conductive metal layer.

19. The article of claim 15, wherein the electronic device is an LED.

20. The article of claim 19 comprising an LED device mounted over the first metal oxide dielectric layer or a pad thereon, which LED device is electrically connected to at least a portion of the first electrically conductive metal layer.

21. A method of making a circuit material comprising
providing a metallic core substrate that is thermally conductive;
forming at least one through-hole via in the metallic core substrate;
forming metal oxide dielectric layers on opposite sides and in through-hole vias of the metallic core substrate by an oxidative reaction converting metal of the metallic core substrate to metal oxide; and
applying electrically conductive metal layers over the surface of the metal oxide dielectric layers at least on opposite sides of the metallic core substrate.

22. The method of claim 21 wherein the through-hole via is filled with a metal-containing core element electrically connecting the electrically conducive layers on opposite sides of the metallic core substrate during the plating of the electrically conductive metal layers.

23. The method of claim 21 wherein the through-hole via is filled with a metal-containing core element electrically connecting the electrically conducive layers on opposite sides of the metallic core substrate following application of the electrically conductive metal layers, wherein the metal-containing core element is made by filling the through-hole via with a metallic paste comprising metal particles and an organic resin.

24. The method of claim 21 wherein, after forming the metal oxide dielectric layers and before applying electrically conductive metal over the surface of the metal oxide dielectric layers, coating a metallic seed layer onto the surface of the metal oxide layers.

25. The method of claim 21 wherein, after forming the metal oxide dielectric layers and before applying the electrically conductive metals layer over the surface of the metal oxide dielectric layers, coating metal oxide dielectric layers with an adhesion-improving material.

26. The method of claim 21 further comprising, after forming metal oxide dielectric layers, coating the layers with a metallic seed layer and, before applying the electrically conductive metal layers, applying a resist coating to the coated metal oxide dielectric layers, exposing the resist, developing the resist [areas exposed are removed], plating electrically conductive metal layers over the metal oxide dielectric layers in areas where the resist has been developed, stripping the resist, and removing the metallic seed layers from areas that have not been plated with electrically conductive metal layers.

27. The method of claim 21 further comprising, after applying a copper layer onto the surface of the metal oxide dielectric layers, dividing the circuit material into a plurality of smaller panels each having dimensions within the range of about 4.0 to 5.0 inches on each of two sides.

28. The method of claim 21, wherein the metal layer is patterned and wherein the method further comprises mounting an electronic device onto the patterned circuit material.

29. The method of claim 21 comprising forming the metal oxide dielectric layers by positioning the metallic core substrate in an electrolysis chamber containing an aqueous electrolyte and an electrode, wherein the metallic core substrate and the electrode are in contact with the aqueous electrolyte, and electrically biasing the substrate with respect to the electrode by applying a sequence of voltage pulses of alternating polarity for a predetermined period of time, positive voltage pulses anodically biasing the substrate with respect to the electrode and negative voltage pulses cathodically biasing the substrate with respect to the electrode, in which the amplitude of the positive and negative voltage pulses are controlled.

30. The method of claim 29 wherein the electrolyte is colloidal and comprises solid particles dispersed in an aqueous phase, in which the electrolyte comprises a proportion of solid particles having particle dimensions of less than 100 nanometers and wherein the solid particles from the electrolyte are incorporated into growing metal oxide dielectric layers.

31. The method of claim 29 wherein the method of forming the metal oxide dielectric layers on the surface of the metallic core substrate comprises positioning the metallic core substrate in an electrolytic chamber containing a colloidal electrolyte comprising solid particles dispersed in an alkaline aqueous phase, the chamber also containing an electrode, at least a portion of both sides of the metallic core substrate and at least a portion of the electrode contacting the electrolyte, and electrically biasing the substrate relative to the electrode for a predetermined period of time to generate metal-oxide-containing dielectric layers on the metallic core substrate by applying a series of bipolar electric pulses such that the polarity of the substrate cycles from being anodic with respect to the electrode to being cathodic with respect to the electrode, the metal oxide-containing layers being formed during periods of the cycle during which the substrate is anodic with respect to the electrode, wherein the solid particles migrate toward the surface of the substrate under the influence of an applied electric field and are incorporated into the metal-oxide-containing dielectric layers to form the metal oxide dielectric layers.
